(19) United States
(12) Patent Application Publication
(10) Pub. No.: US 2012/0050960 A1
(43) Pub. Date: Mar. 1, 2012

(54) SIMPLIFIED HINGE AND A PORTABLE ELECTRONIC DEVICE WITH THE SAME

(76) Inventor: Hsiang-Chi CHIEN, Shulin City (TW)

(21) Appl. No.: 12/874,207

(22) Filed: Sep. 1, 2010

(51) Int. Cl. E05D 11/10; H05K 5/00

(52) U.S. Cl. 361/679.01; 16/319

(57) ABSTRACT

A simplified hinge is mounted between a cover and a base of a portable electronic device. The simplified hinge has a pintle connected to the base, a main linking sheet connected to the cover and a resilient washer and a positioning washer abutting each other and mounted around the pintle. The resilient washer has a resilient segment protruding toward one side. The positioning washer has corresponding positioning protrusion or detent. With the elasticity of the resilient segment, the resilient washer generates torsion when rotating between the positioning washer and the pintle. Furthermore, the positioning protrusion or detent selectively engages with the resilient segment to provide positioning function. Therefore, the resilient washer provides not only the torsion but also the positioning function so that the simplified hinge has a simplified structure and its volume is effectively reduced.

### BACKGROUND OF THE INVENTION

1. Field of the Invention

The present invention relates to a simplified hinge, especially to a simplified hinge mounted between a cover and a base of an electronic device to allow the cover to pivot relative to the base.

2. Description of the Prior Arts

Conventional hinges have some elements providing positioning function and have other elements providing torsion by abrasion.

For example, a conventional hinge as disclosed in U.S. Pat. No. 7,533,446, which is incorporated herein by reference, comprises two positioning washers with corresponding protrusions and detents, which are normally called cams in this art. The positioning washers or cams are rotated relative to each other to selectively engage the corresponding protrusions and detents to provide positioning function; specifically, the positioning function means that when the cover is getting to be closed to a certain angle, for example 15 degrees, the cover will automatically falls to facilitate the latching; this is because the protrusions of cams are sliding into in the detents. On the other hand, when the cover is rotated to open to certain angles, for example at about 120˜435 degrees, the cover will be automatically positioned to suit uses' best viewing angle. All is normally called auto-lock capability.

Accordingly, various contours of the cams have been designed to meet different desires and to limit the cover from over rotating so that the electronic wires in the hinge will not be damaged. Further, multiple resilient washers push the positioning washers or cams to keep them abutting each other so that they rub against each other to provide torsion. Similar conventional hinges are also disclosed in U.S. Pat. Nos. 7,171,247, 6,862,779, 7,082,642, 7,219,393 and U.S. Patent Application Publications 2006/0005353, 2005/0155183 and 2005/0039301, each of which is incorporated herein by reference. These kinds of hinge are widely used in portable electronic devices such as laptops and mobile phones. From these references, it is noted that the success of adjusting and positioning the cover of the electronic device at a certain angle relies on the cooperation of positioning washers (cams) and resilient washers.

Another conventional hinge as disclosed in U.S. Pat. No. 5,269,047, which is incorporated herein by reference, comprises multiple resilient disks. The resilient disks force other components to rub against each other to provide torsion. Similar conventional hinges are also disclosed in U.S. Pat. Nos. 5,772,351, 5,913,351, 5,970,580, 5,940,936, 6,163,928, each of which is incorporated herein by reference. It is obvious that these kinds of hinges do not have cams to provide auto-lock capability; therefore, they will not facilitate closing of the cover and latching, nor are they automatically positioned or locked at certain angles when cover is rotated to open.

Considering the functions that a conventional hinge should provide, positioning function and torsion are necessary and important functions. Because hinges with cams are usually capable of passing its life test, the second types of conventional hinges are getting out of market and replaced by the first types of conventional hinges.

Also, from the above description, positioning function (or called auto-lock capability) and torsion are provided by different components in the conventional hinges. As nowadays the cost reduction will be first priority, the conventional hinges with complex and many components will inevitably increase the cost. Furthermore, the more components the conventional hinges have, the larger the conventional hinges are. Sizes of portable electronic devices need to be reduced to satisfy users' demand, and the larger conventional hinges conflict with the trend.

To overcome the shortcomings, the present invention provides a simplified hinge to mitigate or obviate the aforementioned problems.

### SUMMARY OF THE INVENTION

The main objective of the present invention is to provide a simplified hinge, which is with fewer components while it still achieves positioning function and having enough torque for the portable electronic device.

The simplified hinge is mounted between a cover and a base of a portable electronic device. The simplified hinge has a pintle connected to the base, a main linking sheet connected to the cover and a resilient washer and a positioning washer abutting each other and mounted around the pintle. The resilient washer has a resilient segment protruding from one side, and the positioning washer has corresponding positioning protrusion or detent to fit with the resilient segment of the resilient washer. With the elasticity of the resilient segment, the resilient washer generates torsion when rotating between the positioning washer and the pintle. Furthermore, the positioning protrusion or detent of the positioning washer selectively engages with the resilient segment to provide positioning function. Therefore, the resilient washer provides not only the torsion but also the positioning function so that the simplified hinge has a simplified structure and its size is effectively reduced.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a first embodiment of a simplified hinge in accordance with the present invention;

FIG. 2 is an exploded perspective view of the simplified hinge in FIG. 1;

FIG. 3 is another exploded perspective view of the simplified hinge in FIG. 4 is a perspective view of a portable electronic device in accordance with the present invention with the simplified hinge in FIG. 1;

FIG. 5 is an operational side view of the simplified hinge in FIG. 1;

FIG. 6 is another operational side view of the simplified hinge in FIG. 1;

FIG. 7 is a perspective view of a second embodiment of a simplified hinge in accordance with the present invention;

FIG. 8 is an exploded perspective view of the simplified hinge in FIG. 7;

FIG. 9 is an operational side view of the simplified hinge in FIG. 7;

FIG. 10 is another operational side view of the simplified hinge in FIG. 7;

FIG. 11 is a perspective view of another embodiment of a portable electronic device in accordance with the simplified hinge in FIG. 7;

FIG. 12 is an exploded perspective view of a third embodiment of a simplified hinge in accordance with the present invention; and

FIG. 13 is an exploded perspective view of a fourth embodiment of a simplified hinge in accordance with the present invention.

### DETAILED DESCRIPTION OF THE PREFERRED EMBODIMENTS

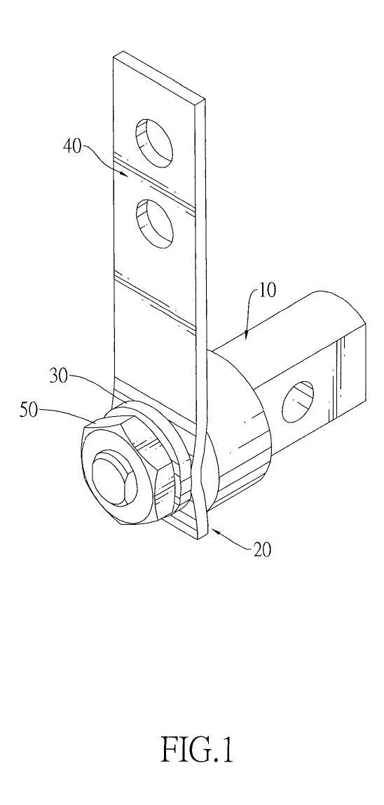

With reference to FIG. 1, a simplified hinge in accordance with the present invention comprises a pintle 10, a resilient washer 20, a linking sheet 40, a positioning washer 30 and a fastener 50.

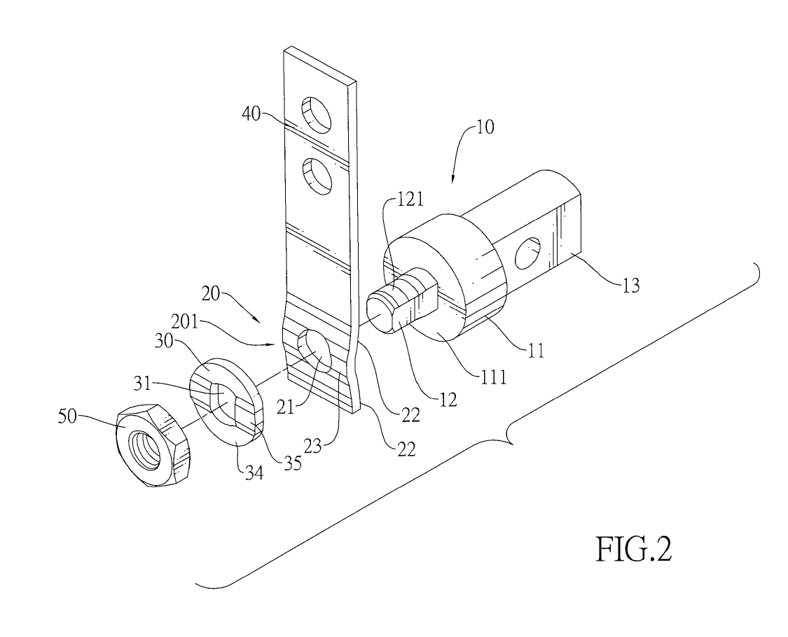

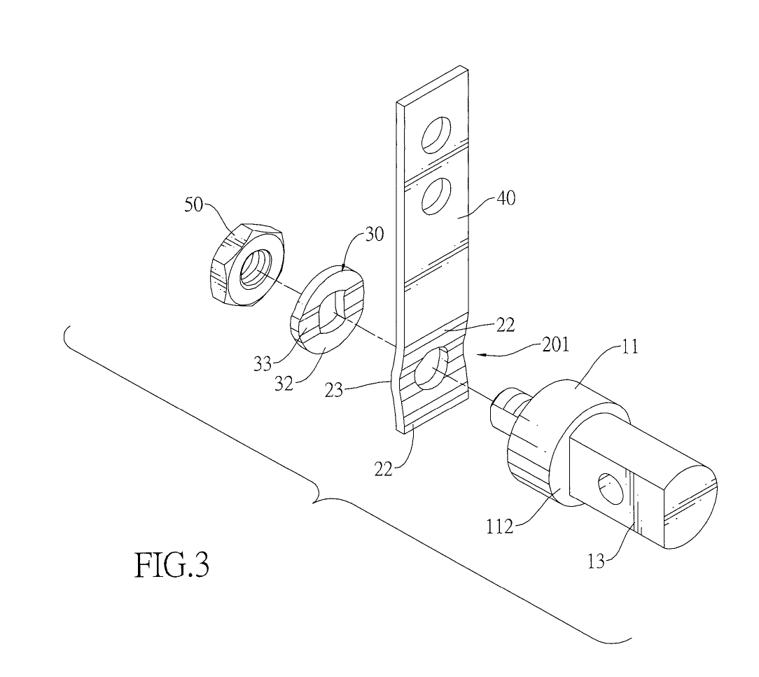

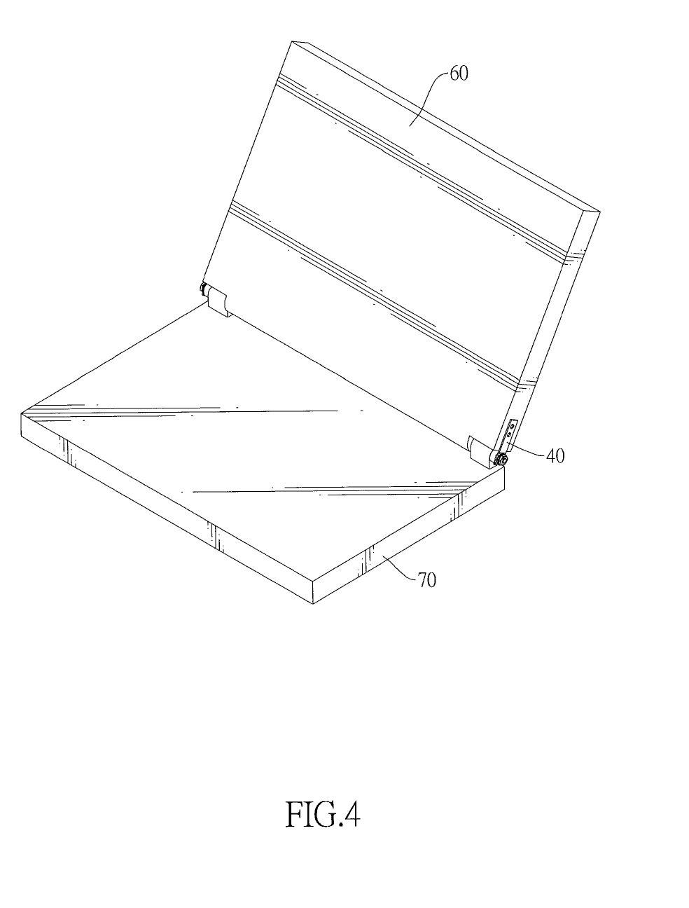

With reference to FIGS. 2 and 3, the pintle 10 has an enlarged head 11, a mounting rod 12 and a connecting rod 13. The enlarged head 11 has a first side 111 and a second side 112. The mounting rod 12 protrudes longitudinally out from the first side 111 of the enlarged head 11. The mounting rod 12 may be non-circular in cross section. The connecting rod 13 protrudes longitudinally out from the second side 112 of the enlarged head 11.

The resilient washer 20 is mounted rotatably around the mounting rod 12 of the pintle 10 via a circular hole 21. The resilient segment 201 protrudes from one side of the resilient washer 20 to form a positioning protrusion 23 and thus correspondingly form a positioning detent on the other side of the resilient washer 20; accordingly, the upper and lower margins of the positioning detent are defined as two abutting ends 22. The abutting ends 22 of the resilient segment 201 abut against the first side 111 of the enlarged head 11 of the pintle 10. When the positioning protrusion 23 is pressed, the abutting ends 22 moves outwardly on the first side 111 because the resilient segment 201 is flexible.

The main linking sheet 40 extends out from the resilient washer 20.

The positioning washer 30 is mounted slidably and non-rotatably around the mounting rod 12 via a keyed hole 31. The positioning washer 30 has a first side 34, a second side 32, a positioning detent 33 and a positioning protrusion 35. The second side 32 of the positioning washer 30 abuts against the positioning protrusion 23 of the resilient washer 20. The positioning detent 33 is formed in the second side 32 of the positioning washer 30 and selectively engages the positioning protrusion 23 of the resilient washer 20, and thus the positioning protrusion 35 of the positioning washer 30 protrudes on the first side 34 of the positioning washer 30.

The fastener 50 is mounted securely at the end of the mounting rod 12 and abuts against the first side 34 of the positioning washer 30. The fastener 50 urges the positioning washer 30, the resilient washer 20 and the enlarged head 11 of the pintle 11 to abut against each other. Therefore, the abutting ends 22 of the resilient segment 201 contact with the first side 111 of the enlarged head 11. The positioning detent 33 of the positioning washer 30 selectively engages the positioning protrusion 23 to provide desired positioning function or so-called auto-lock capability. The fastener 50 may be a nut to screw onto the threaded part 121 of the mounting rod 12. It is obvious that the fastener 50 can be eliminated if the end of the mounting rod 12 is flatted as a rivet to avoid the positioning washer 30 from escape.

With reference to FIGS. 1 and 4, a portable electronic device in accordance with the present invention comprises a cover 60, a base 70 and the simplified hinge as described. The connecting rod 13 of the pintle 10 is connected securely to the base 70. The main linking sheet 40 is attached securely to the base 60. When the cover 60 is pivoted relative to the base 70, the main linking sheet 40 and the resilient washer 20 are rotated relative to the pintle 10 and the positioning washer 30.

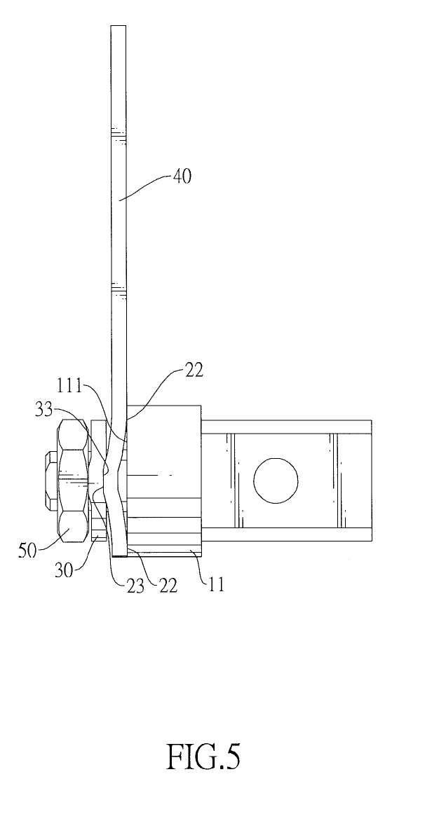

With reference to FIG. 5, this figure shows that the positioning protrusion 23 of the resilient washer 20 falls in and engages with positioning detent 33 of the positioning washer 30 when the cover 60 is fully closed on the base 70. This helps the cover 60 be positioned at zero degree so as to achieve the positioning function. Also, at this time, the resilient washer 20 is clamped between the positioning washer 30 and the enlarged head 11 of the pintle 10, and the two abutting ends 22 respectively contact with the first side 111 of the enlarged head 11.

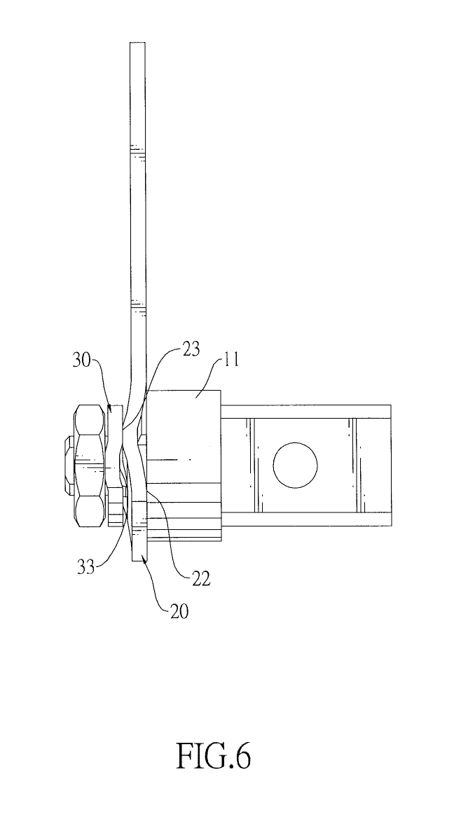

When the cover 60 is getting opened, the positioning washer 30 remains steady on the mounting rod 12 while resilient segment 201 of the resilient washer 20 with elasticity is then pressed by the positioning washer 30 and deformed to become flatter so that the abutting ends 22 move outwardly on the first side 111 of the enlarged head 11 and thus the abrasion results in torsion as shown in FIG. 6. When the cover 60 is fully opened to 180 degrees, the positioning protrusion 23 of the resilient washer 20 engages the positioning detent 33 of the positioning washer 30 again, wherein the two abutting ends 22 move inwardly and back to the original position. Therefore, the resilient washer 20 provides not only the torsion but also the positioning function so that the hinge as described has a simplified structure and its volume is effectively reduced. However, it should be noted that a person in the art may easily change the numbers of positioning protrusions and detents on the positioning washer and the resilient washer. That is to say, the contour of the positioning washer and the resilient washer are easily configured in a manner such that the cover can be automatically positioned at any desired angle.

A hinge for a portable electronic device must pass the life test; namely, the hinge has to be opened and closed for over twenty thousand times. When the hinge is continually opened and closed, the abutting ends 22 of the resilient segment 201 not only keep rubbing against and but also move outwardly and inwardly on the first side 111 of the enlarged head 11. And this will greatly and directly influences the lifespan of the resilient washer 20 of the hinge as described. Therefore, the following alternative embodiments will show how to modify the present invention to prolong the lifespan of the resilient washer 20.

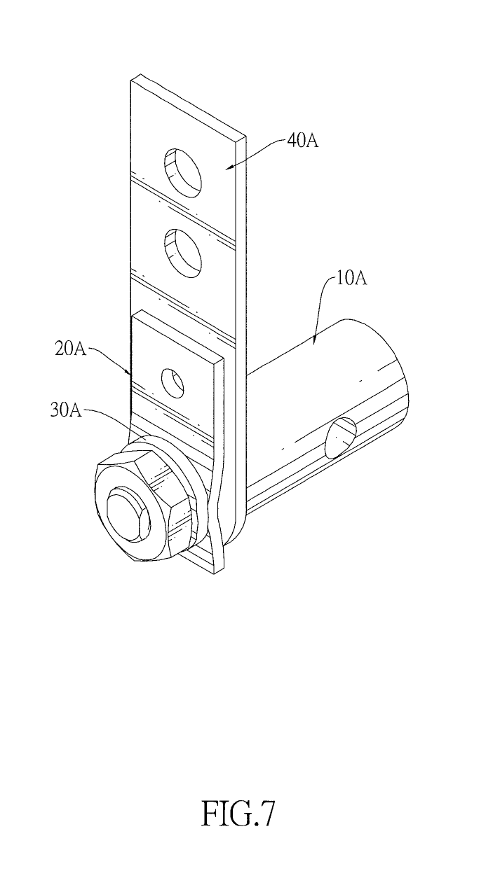

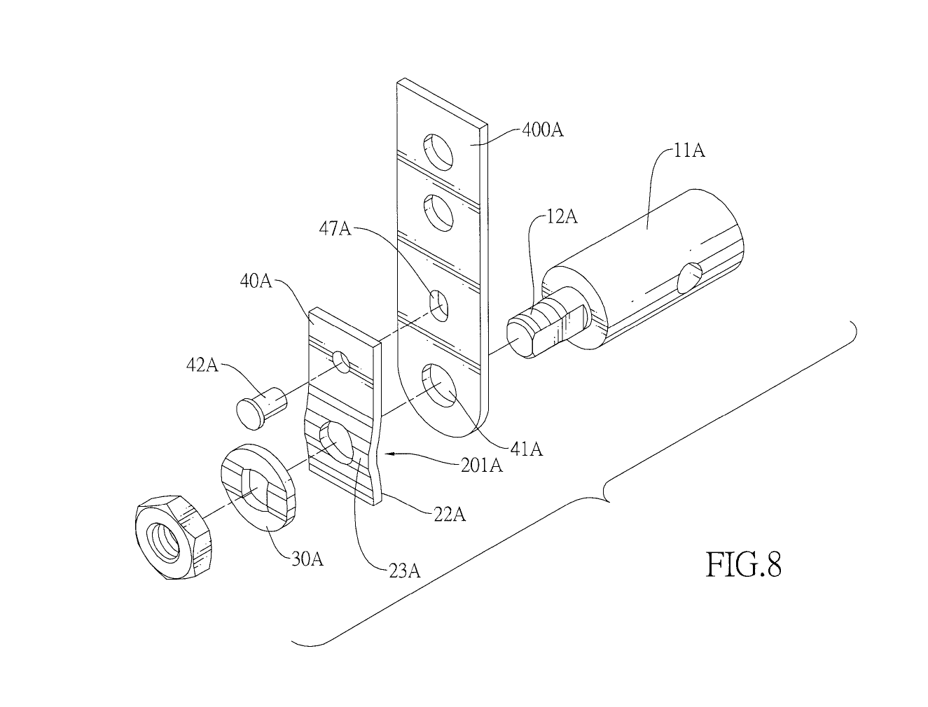

A preferred embodiment as shown in FIGS. 7 and 8 further comprises an additional linking sheet 400A. The pintle 10A has the enlarged head 11A and the mounting rod 12A. The enlarged head 11A is attached securely to the base of the portable electronic device. The additional linking sheet 400A is mounted around the mounting rod 12A via a circular hole 41A. A pin 42A is mounted through the additional linking sheet 400A and the main linking sheet 40A to hold the additional linking sheet 400A and the resilient washer 20A together. In a preferred embodiment, the additional linking sheet 400A is formed with a slot 47A therethrough so as to be inserted by the pin 42A, and thus the main linking sheet 40A is capable of slightly slide upwardly and downwardly on the additional linking sheet 400A during the rotation of the additional linking sheet 400A. The additional sheet 400A is attached securely to the base of the portable electronic device so that it also brings the resilient washer 20A to rotate. The abutting ends 22A of the resilient segment 201A abut against the additional linking sheet 400A.

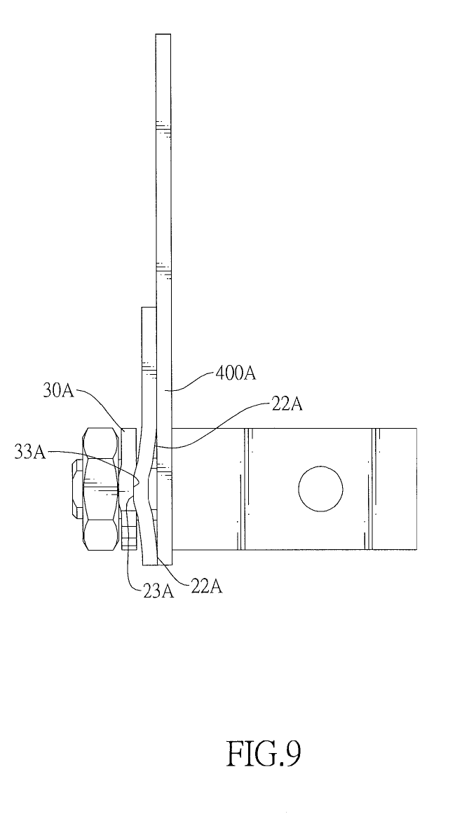

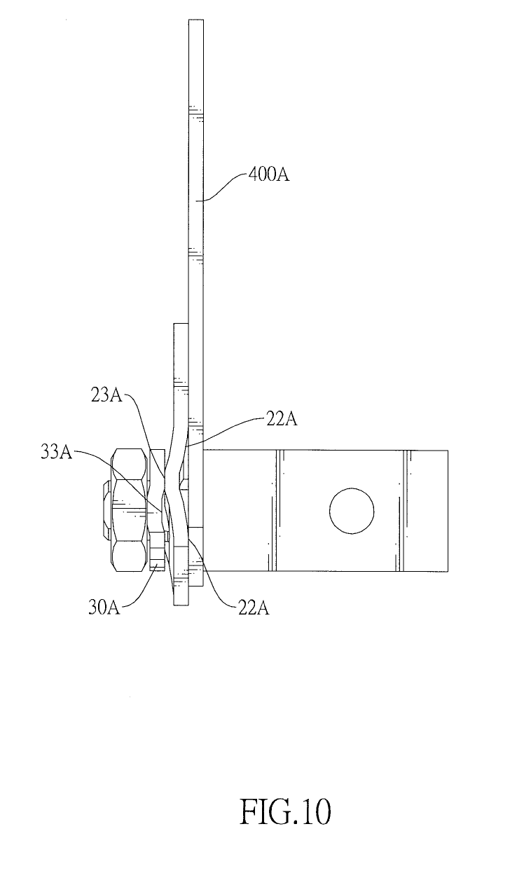

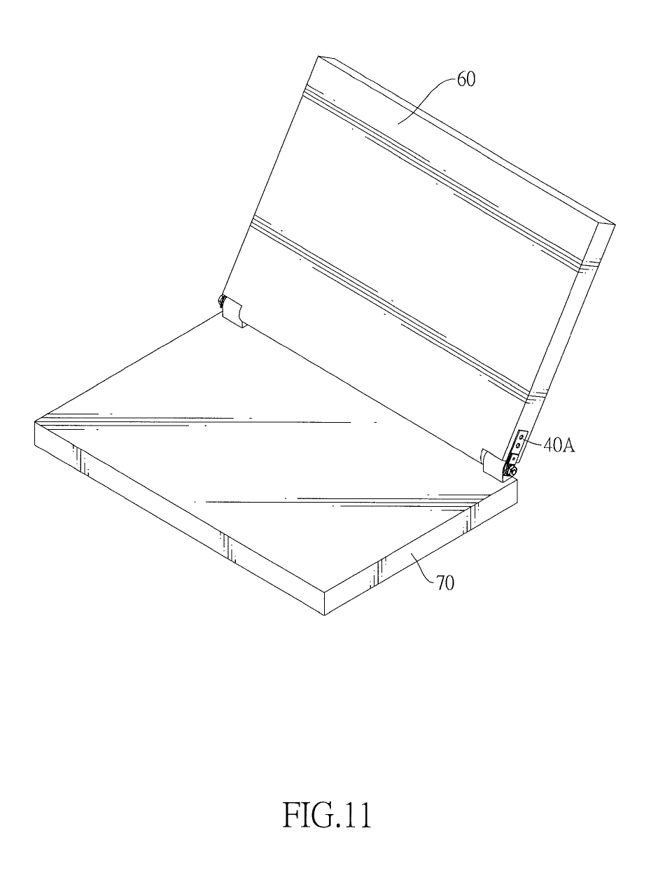

With further reference to FIG. 9, this figure shows the status of the hinge when the cover 60 is closed and parallel to the base 70. The resilient washer 20A is clamped between the positioning washer 30A and the additional linking sheet 400A. When the cover 60 is rotated, the resilient segment 201A is pressed and deformed by positioning washer 30A; thus, the abutting ends 22A respectively move upwardly and downwardly only on the additional linking sheet 400A. Therefore, the resilient washer 20A experiences less abrasion and its lifespan can be prolonged thereof. Further, the positioning protrusion 23A of the resilient washer 20A selectively engages the positioning detent 33A of the positioning washer 30A to provide positioning function. Moreover, since the additional linking sheet 400A is rotated relative to the pintle 10A, the additional linking sheet 400A rubs against the full first side of pintle 10A, which can stabilize the relative rotation better than only use the abutting ends to rub against the pintle which results in shaking during rotation.

The positioning protrusions and positioning detents on the resilient washer and the positioning washer may be altered without reducing the effects, such as the quantity and the location.

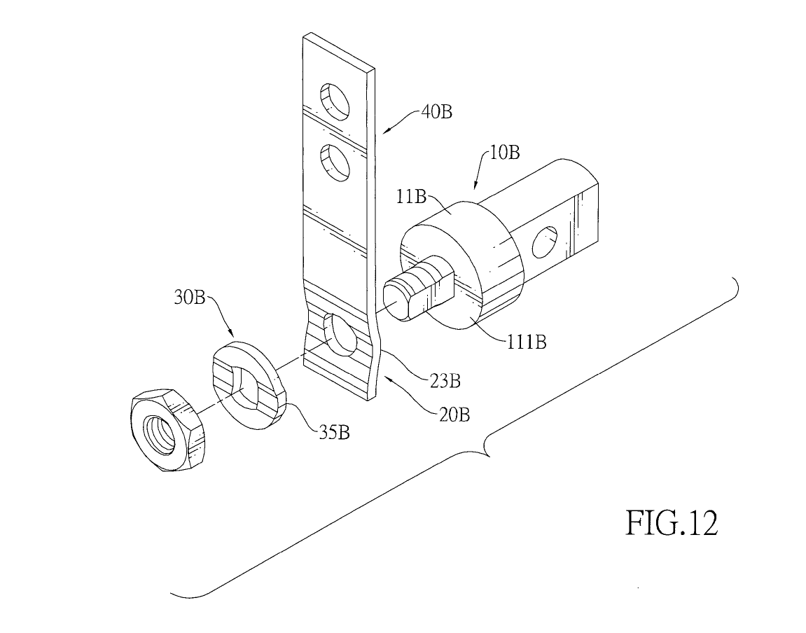

Another preferred embodiment is shown in FIG. 12. The positioning protrusion 23B of the resilient washer 20B protrudes from one side of the resilient washer 20B; namely, the positioning protrusion 23B faces to the first side 111B of the enlarged head 11B; meanwhile, this can form a positioning detent in the other side of the resilient washer 20B. The positioning protrusion 23B rubs against the first side 111B of the enlarged head 11B of the pintle 10B to provide torsion. The positioning protrusion 35B of the positioning washer 30B abuts against the resilient washer 20B and selectively engages with the positioning detent in the resilient washer 20B to provide positioning function. Therefore, even though the related locations of the positioning protrusions and detents are reversed, the resilient washer 20B still provides both torsion and positioning function. However, the lifespan of the resilient washer 20B directly influences the lifespan of the hinge as described. The following alternative embodiments will show how the lifespan of the resilient washer 20B can be prolonged.

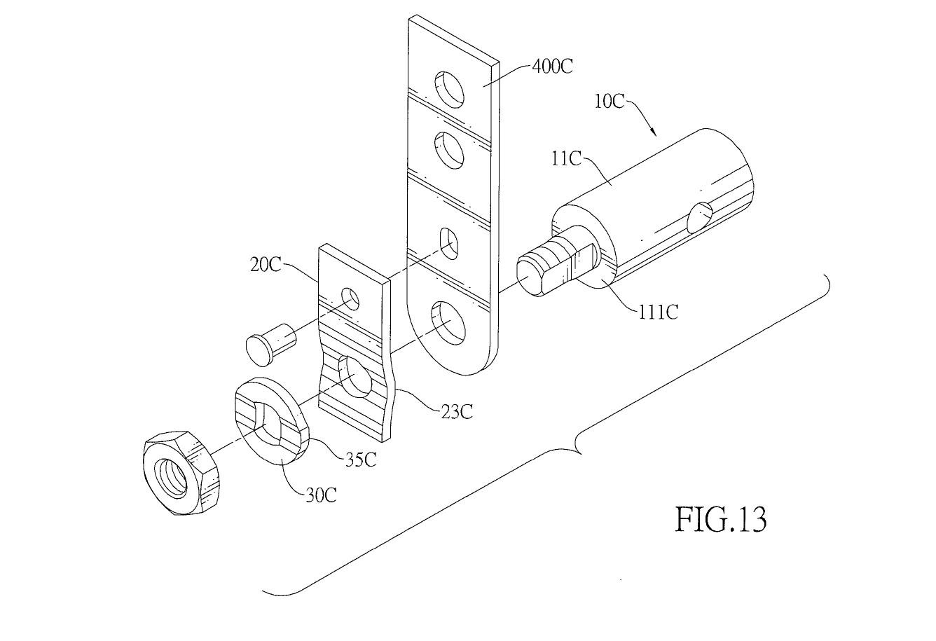

With reference to FIG. 13, the additional linking sheet 400C is clamped between the first side 111C of the enlarged head 11C of the pintle 10C and the resilient washer 20C. The positioning protrusion 23C of the resilient washer 20C protrudes from one side of the resilient washer 20C and accordingly forms a positioning detent in the other side of the resilient washer 20C. The positioning protrusion 35C of the positioning washer 30C selectively engages the positioning detent of the resilient washer 20C to provide positioning function. When the additional linking sheet 400C is rotated relative to the pintle 10C, the additional linking sheet 400C rubs against the pintle 10C to stabilize the relative rotation instead of using only the resilient washer 20C to rub against the pintle 10C. Therefore, the resilient washer 20C has less abrasion and its lifespan can be prolonged thereof.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A simplified hinge comprising:
a pintle having
an enlarged head;
a mounting rod protruding longitudinally out from the enlarged head;
a resilient washer mounted rotatably around the mounting rod of the pintle and having
a resilient segment protruding from one side of the resilient washer to form a positioning protrusion and to form a positioning detent on the other side of the resilient washer;
a main linking sheet connected to the resilient washer;
a positioning washer mounted slidably and non-rotatably around the mounting rod and having
a positioning detent formed in one side of the positioning washer and selectively engaging the positioning protrusion of the resilient washer; and
a fastener mounted securely around the mounting rod and urging the positioning washer, the resilient washer and the enlarged head of the pintle to abut against each other.

2. The simplified hinge as claimed in claim 1, wherein
the enlarged head of the pintle has a first side;
the resilient washer is clamped between the enlarged head and the positioning washer;
the resilient segment of the resilient washer having an upper abutting end and a lower abutting end opposite to the upper abutting end; and
the upper and lower abutting ends of the resilient segment of the resilient washer abut against the first side of the enlarged head.

3. The simplified hinge as claimed in claim 1 further comprising an additional linking sheet mounted around the mounting rod, slidably attached to the main linking sheet and clamped between the resilient washer and the enlarged head, wherein the upper and lower abutting ends of the resilient segment abut against the additional linking sheet.

4. The simplified hinge as claimed in claim 1, wherein
the mounting rod of the pintle is non-circular in cross section; and
the positioning washer has a keyed hole engaging the mounting rod.

5. The simplified hinge as claimed in claim 2, wherein
the mounting rod of the pintle is non-circular in cross section; and
the positioning washer has a keyed hole engaging the mounting rod.

6. The simplified hinge as claimed in claim 3, wherein
the mounting rod of the pintle is non-circular in cross section; and
the positioning washer has a keyed hole engaging the mounting rod.

7. The simplified hinge as claimed in claim 1, wherein
the mounting rod has a threaded part formed thereon; and
the fastener is a nut screwed on the threaded part.

8. The simplified hinge as claimed in claim 5, wherein
the mounting rod has a threaded part formed thereon; and
the fastener is a nut screwed on the threaded part.

9. The simplified hinge as claimed in claim 6, wherein
the mounting rod has a threaded part formed thereon; and
the fastener is a nut screwed on the threaded part.

10. A portable electronic device with a simplified hinge as claimed in claim 1 comprising a cover and a base, wherein the simplified hinge is mounted between the cover and the base, the main linking sheet is attached securely to the cover, and the pintle is connected securely to the base.

11. A simplified hinge comprising:
a pintle having
an enlarged head;
a mounting rod protruding longitudinally out from the enlarged head;
a resilient washer mounted rotatably around the mounting rod of the pintle and having
a resilient segment protruding toward the enlarged head to form a positioning protrusion on one side of the resilient washer and to form a positioning detent on the other side of the resilient washer;
a main linking sheet extending out from the resilient washer;
a positioning washer mounted slidably and non-rotatably around the mounting rod and having
a positioning protrusion formed on one side of the positioning washer and selectively engaging the positioning detent of the resilient washer; and
a fastener mounted securely around the mounting rod and forcing the positioning washer, the resilient washer and the enlarged head of the pintle to abut against each other.

12. The simplified hinge as claimed in claim 11 further comprising an additional linking sheet mounted around the mounting rod, attached securely to the main linking sheet and clamped between the resilient washer and the enlarged head.

13. The simplified hinge as claimed in claim 11, wherein
the mounting rod of the pintle is non-circular in cross section; and
the positioning washer has a keyed hole engaging the mounting rod.

14. The simplified hinge as claimed in claim 12, wherein
the mounting rod of the pintle is non-circular in cross section; and
the positioning washer has a keyed hole engaging the mounting rod.

15. The simplified hinge as claimed in claim 11, wherein
the mounting rod has a threaded part formed thereon; and
the fastener is a nut screwed on the threaded part.

16. The simplified hinge as claimed in claim 14, wherein
the mounting rod has a threaded part formed thereon; and
the fastener is a nut screwed on the threaded part.
